(19) United States
(12) Patent Application Publication
(10) Pub. No.: US 2012/0298409 A1
(43) Pub. Date: Nov. 29, 2012

(54) CIRCUIT BOARD AND METHOD OF MANUFACTURING THE SAME

(75) Inventors: Soon-chul KWON, Changwon-city (KR); Sang-min LEE, Changwon-city (KR)

(73) Assignee: SAMSUNG TECHWIN CO., LTD., Changwon-city (KR)

(21) Appl. No.: 13/414,793

(22) Filed: Mar. 8, 2012

(30) Foreign Application Priority Data
May 23, 2011 (KR) 10-2011-0048500

(51) Int. Cl. H05K 1/11; H05K 1/00; H05K 3/10

(52) U.S. Cl. 174/262; 29/846; 174/250

(57) ABSTRACT

Provided are a circuit board and a method of manufacturing the same which increase a peel strength between a prepreg and a copper plating layer. The method includes: providing a substrate including a first circuit pattern and a first prepreg; forming a plurality of holes on a top surface of the first prepreg; removing silica fillers contained in inner walls of the plurality of holes; and performing copper plating on the top surface of the first prepreg.

CROSS-REFERENCE TO RELATED PATENT APPLICATION

This application claims priority from Korean Patent Application No. 10-2011-0048500, filed on May 23, 2011, in the Korean Intellectual Property Office, the disclosure of which is incorporated herein by reference in its entirety.

### BACKGROUND

1. Field

Apparatuses and methods consistent with exemplary embodiments relate to a circuit board and manufacturing the same.

2. Description of the Related Art

A circuit board used in a small electronic device such as a cellular phone or a smart phone is required to get smaller. As a solution, a circuit board having a fine circuit pattern formed thereon has developed.

In order to form the fine circuit pattern on the circuit board, an etching process and a semi-additive process are used.

The etching process is a process of forming a circuit pattern by etching a copper layer formed on a substrate which is a general process used to manufacture circuit boards.

A semi-additive process is a process of forming a circuit pattern by using plating which is often used to remedy shortcomings of the etching process.

In such semi-additive process, a copper plating layer is formed on a prepreg. A predetermined level of peel strength needs to be applied between the prepreg and the copper plating layer. For a prepreg used for a semi-additive process, contents of an epoxy resin and silica fillers are increased. Such a prepreg only used for a semi-additive process is expensive, thereby increasing circuit board manufacturing costs.

### SUMMARY

One or more exemplary embodiments may overcome the above disadvantages and other disadvantages not described above. However, it is understood that one or more exemplary embodiment are not required to overcome the disadvantages described above, and may not overcome any of the problems described above.

One or more exemplary embodiments provide a method of manufacturing a circuit board which uses a common prepreg and increases a peel strength between the prepreg and a copper plating layer by increasing a surface area of the prepreg.

One or more exemplary embodiments also provide a circuit board which uses a common prepreg and increases a surface area of the prepreg.

According to an aspect of an exemplary embodiment, there is provided a method of manufacturing a circuit board, the method including: providing a substrate with a first circuit pattern and a prepreg are sequentially stacked on a top surface of the substrate; forming a plurality of holes on a top surface of the prepreg; removing silica fillers contained in inner walls of the plurality of holes; performing copper plating on the top surface of the prepreg; and forming a second circuit pattern connected to the first circuit pattern on the prepreg.

The providing of the substrate may include: preparing the substrate with the first circuit pattern formed on the top surface of the substrate; sequentially disposing the prepreg and a copper foil on the substrate with the first circuit pattern formed on the top surface of the substrate; compressing the copper foil and the prepreg to the substrate; and removing the copper foil.

The copper foil may be a general copper foil, and may be disposed such that a smooth surface of the copper foil adjoins the prepreg. The silica fillers may be removed by using a hydrofluoric acid-containing mixture. After the top surface of the prepreg is swollen, de-smearing may be performed.

The performing of the copper plating may include: forming one or more craters on the top surface of the prepreg to expose some of copper wires included in the first circuit pattern to the outside; forming a seed layer composed of copper by using non-electrolysis means on the prepreg where the one or more holes are formed on the top surface of the prepreg; and forming a copper plating layer on the seed layer by using electrolysis means.

Similarly, a second circuit pattern and a second prepreg may be stacked on a bottom surface of the substrate, and the same processes performed on the first circuit pattern and the first prepreg may be simultaneously performed on the second circuit pattern and the second prepreg to achieve similar results.

According to an aspect of another exemplary embodiment, there is provided a circuit board including: a substrate with a first circuit pattern formed on a top surface of the substrate; a prepreg adhered to the first circuit pattern; a plurality of holes formed on a top surface of the prepreg; and one or more auxiliary holes formed on surfaces of the plurality of holes by removing silica fillers contained in the inner walls of the plurality of holes.

The circuit board may further include: a second circuit pattern formed on a bottom surface of the substrate; a second prepreg adhered to a bottom surface of the second circuit pattern; a plurality of second holes formed on a bottom surface of the second prepreg; and one or more second auxiliary holes formed on surfaces of the plurality of second holes by removing silica fillers contained in the inner walls of the plurality of second holes.

### BRIEF DESCRIPTION OF THE DRAWINGS

The above and other aspects will become more apparent by describing in detail exemplary embodiments with reference to the attached drawings, in which:

FIG. 1 is a flowchart illustrating a method of manufacturing a circuit board, according to an exemplary embodiment;

FIGS. 2A through 8 are cross-sectional views sequentially illustrating processes of the method of FIG. 1, according to an exemplary embodiment; and

FIG. 9 is an enlarged cross-sectional view taken along line A-A′ of FIG. 6, for explaining a structure of the circuit board, according to an exemplary embodiment.

### DETAILED DESCRIPTION

Hereinafter, exemplary embodiments will be described in detail with reference to the attached drawings. In the drawings, the same reference numerals denote the same members.

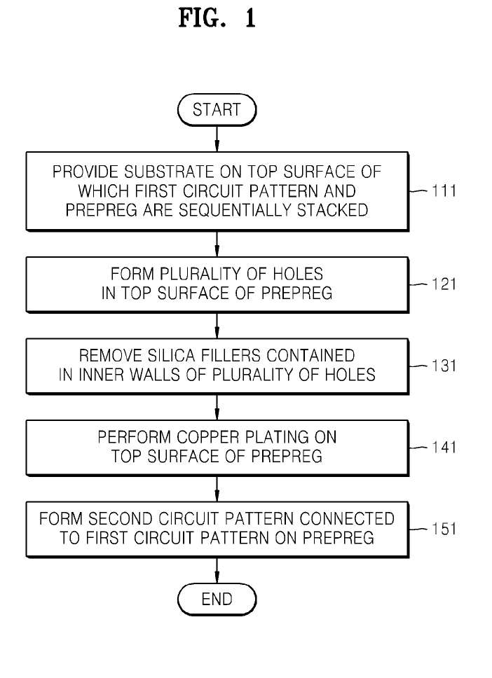

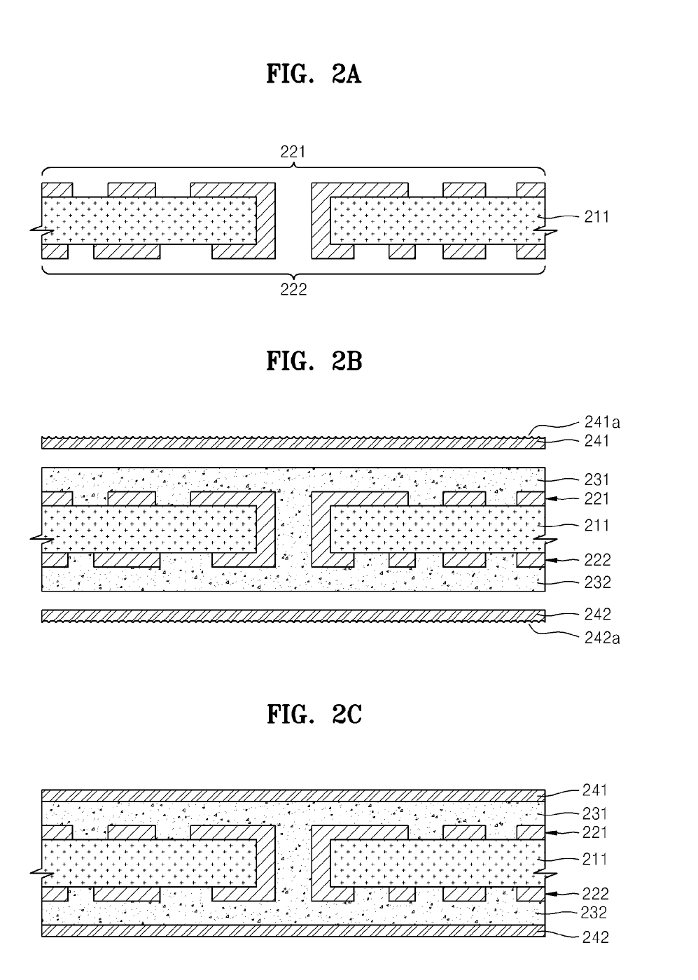

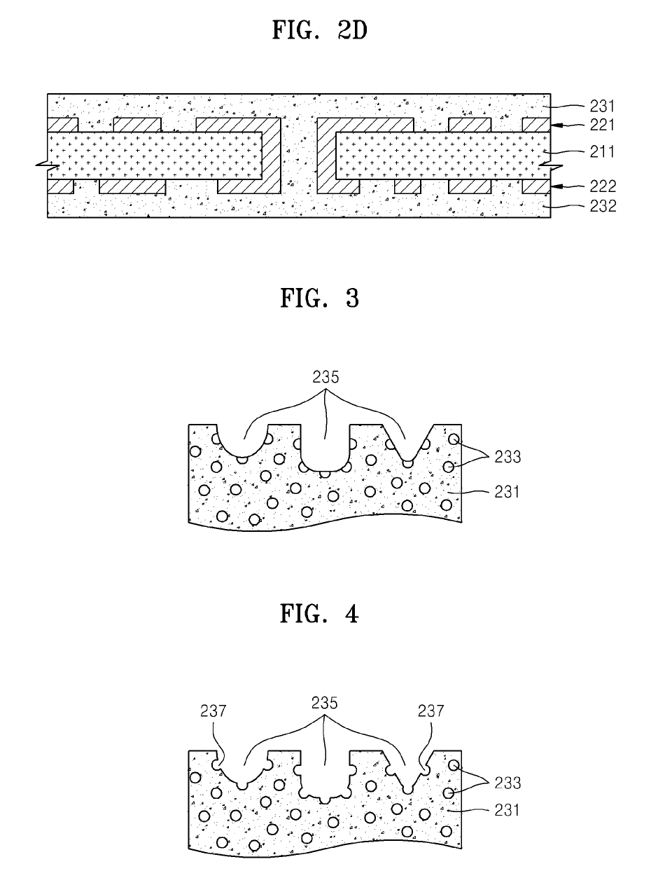

FIG. 1 is a flowchart illustrating a method of manufacturing a circuit board 201, according to an exemplary embodiment. FIGS. 2A through 8 are cross-sectional views sequentially illustrating exemplary embodiments of the method of FIG. 1. Referring to FIG. 1, a method of manufacturing a circuit board 201 includes five (5) separate processes. (111 through 151). The method of manufacturing the circuit board 201 illustrated in FIG. 1 will be explained in detail with reference to FIGS. 2A through 8.

In the first process 111, a first circuit pattern 221 and a first prepreg 231 are sequentially stacked on a top surface of a substrate 211, and a second circuit pattern 222 and a second prepreg 232 are sequentially stacked on a bottom surface of the substrate 211. The first process 111 is performed by performing the following four steps.

In the first step, referring to FIG. 2A, the substrate 211, where the first circuit pattern 221 is formed on the top surface and the second circuit pattern 222 is formed on the bottom surface, is prepared.

The substrate 211 may be formed of an insulating material through which an electric current does not flow. For example, any one of glass cloths such as FR4 or FR5, an epoxy matrix, and a polyimide-based material can be used. The substrate 211 may also be formed of a polymer material such as poly(methyl methacrylate) or polycarbonate. The substrate 211 may be a printed circuit board (PCB) or a flexible printed circuit board (FPCB).

In order to form the first and second circuit patterns 221 and 222 on the top and bottom surfaces of the substrate 211, conductive layers (not shown) formed of copper or the like are formed on the top and bottom surfaces of the substrate 211. In order to form the first and second circuit patterns 221 and 222 by using the conductive layers, a dry film resist or a photoresist may be applied to the conductive layers. Exposure, developing, and exfoliation using a mask may be performed after applying the dry film resist or the photoresist. When the exposure, developing, and exfoliation are completed, the first and second circuit patterns 221 and 222 are formed. The exposure, developing, and exfoliation are well known and thus a detailed explanation thereof will not be given.

In the second step, referring to FIG. 2B, the first and second prepregs 231 and 232 and first and second copper foils 241 and 242 are sequentially disposed on the top and bottom surfaces of the substrate 211 on which the first and second circuit patterns 221 and 222 are formed.

The first and second copper foils 241 and 242 may be common copper foils. In general, a copper foil has one surface which is soft and the other surface which is rougher than the other surface. In the present embodiment, soft surfaces of the first and second copper foils 241 and 242 face the first and second prepregs 231 and 232, and rough surfaces of the copper foils 241 and 242 are exposed to the outside. As such, it is very easy to separate the first and second copper foils 241 and 242 from the first and second prepregs 231 and 232 after the first and second copper foils 241 and 242 are compressed to the first and second prepregs 231 and 232. Also, since the first and second copper foils 241 and 242 are common copper foils, circuit board manufacturing costs are drastically reduced.

The first and second prepregs 231 and 232 each formed of an insulating material, through which electric current does not flow, insulate the first and second circuit patterns 221 and 222. The first and second prepregs 231 and 232 are prepregs commonly used with a multi-layer substrate, instead of being prepregs only used for a semi-additive process. Since prepregs used only in a semi-additive process are expensive, circuit board manufacturing costs are increased. Therefore, according to the exemplary embodiment, the first and second prepregs 231 and 232 are prepregs commonly used in the multi-layer substrate in order to reduce circuit board manufacturing costs.

In the third step, referring to FIG. 2C, the first and second copper foils 241 and 242 and the first and second prepregs 231 and 232 are compressed to the top and bottom surfaces of the substrate 211. That is, the first and second prepregs 231 and 232 are compressed to the substrate 211 by simultaneously applying pressures to a top surface 241 a of the first copper foil 241 and a bottom surface 242a of the second copper foil 242. Accordingly, the first and second prepregs 231 and 232 are filled in an empty space where the first and second cover patterns 221 and 222 are not formed to improve an insulating property between wires (not shown) constituting the first and second circuit patterns 221 and 222 as shown in FIG. 2C. Also, since the first and second prepregs 231 and 232 are compressed to the substrate 211 by using a compression process requiring no additional after the compression process, circuit board manufacturing costs are reduced and damage factors for the circuit board 201 are reduced.

In the fourth step, referring to FIG. 2D, the first and second copper foils 241 and 242 are separated from the first and second prepregs 231 and 232 to be removed. That is, since the soft surfaces of the copper foils 241 and 242 are adhered to the first and second prepregs 231 and 232, the first and second copper foils 241 and 242 may be simply and easily separated from the first and second prepregs 231 and 232 without using an additional apparatus or method. Also, since the soft surfaces of the first and second copper foils 241 and 242 are adhered to the first and second prepregs 231 and 232, the amount of smears of the first and second copper foils 241 and 242 attached to the first and second prepregs 231 and 232 is very small, thereby enabling a de-smearing process to be smoothly performed.

In the second process 121, a plurality of holes 235 are formed in surfaces 231a and 232a of the first and second prepegs 231 and 232. The plurality of holes 235 may be formed by performing de-smearing on the first and second prepregs 231 and 232. The plurality of holes 235 may not have fixed shapes but rather have various shapes as shown in FIG. 3. That is, since the plurality of holes 235 may be formed to have various shapes such as semicircular shapes, quadrangular shapes, or triangular shapes, the plurality of holes 235 are not limited to specific shapes. Also, depths of the plurality of holes 235 may be slightly different from one another. Meanwhile, while the de-smearing is performed, all smears attached to the first and second prepregs 231 and 232 are removed.

In order to smoothly perform the de-smearing, swelling may be further performed on the surfaces 231a and 232a of the first and second prepregs 231 and 232. That is, the surfaces 231a and 232a of the first and second prepregs 231 and 232, which are compressed to the substrate 211 and then cured, are swollen, and the swollen portions of the surfaces 231 a and 232a of the first and second prepregs 231 and 232 are removed during the de-smearing, thereby enabling the plurality of holes 235 to be easily formed on the surfaces 231a and 232a of the first and second prepregs 231 and 232. A common technology in this field may be used to swell the first and second prepregs 231 and 232.

In the third process 131, silica fillers 233 contained in inner walls of the plurality of holes 235 are removed. As a result, roughness of the surfaces 231a and 232a of the first and second prepregs 231 and 232 are greatly increased as shown in FIG. 6. That is, unevenness of the surfaces 231a and 232a of the first and second prepregs 231 and 232 are increased to increase surface areas, thereby increasing surface roughness.

The first and second prepregs 231 and 232 which are common prepregs contain the silica fillers 233 which are particles as shown in FIG. 4. The silica fillers 233 may be removed by a hydrofluoric acid. However, once a hydrofluoric acid is used, damage to the first and second prepregs 231 and 232 may be severe. Accordingly, only the silica fillers 233 contained in the first and second prepregs 231 and 232 are selectively removed by using a hydrofluoric acid-containing mixture in which an appropriate amount of hydrofluoric acid is contained. As such, since only the silica fillers 233 are removed by using the hydrofluoric acid-containing mixture, auxiliary holes 237 are formed on surfaces of the plurality of holes 235. Surface areas of the first and second prepregs 231 and 232 are drastically increased due to the auxiliary holes 237. That is, roughness of the surfaces 231 a and 232a of the first and second prepregs 231 and 232 are greatly increased.

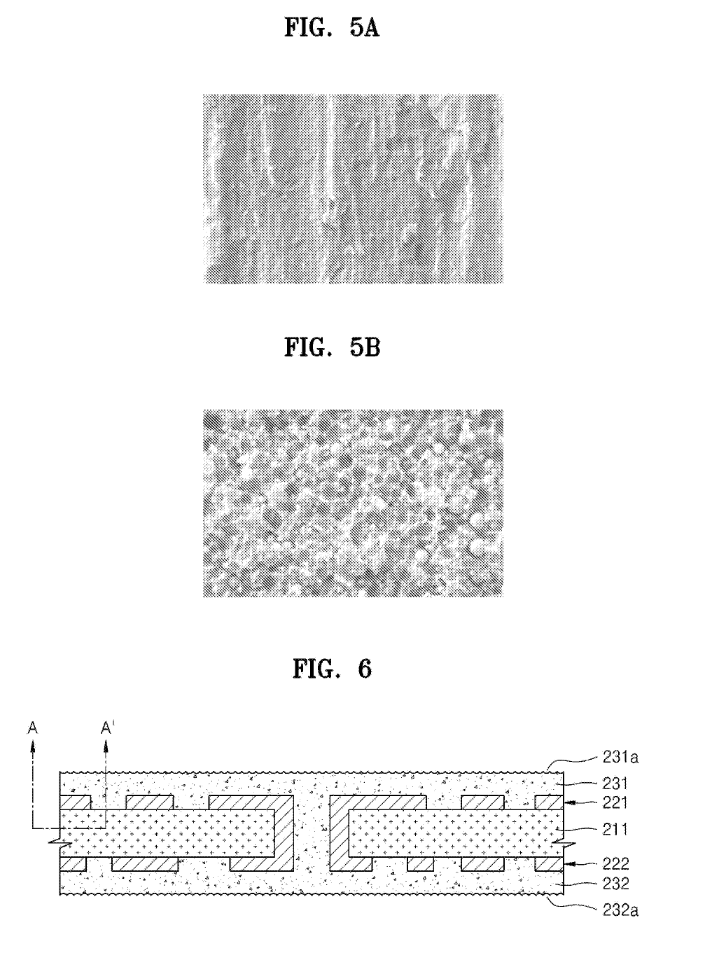

FIG. 5A is a photograph of the surfaces 231a and 232a of the first and second prepregs 231 and 232 before the second and third processes 121 and 131 of the method of FIG. 1 are performed. FIG. 5B is a photograph of the surfaces 231a and 232a of the first and second prepregs 231 and 232 after the second and third processes 121 and 131 of the method of FIG. 1 are performed. As shown in FIG. 5B, since many holes are formed in the surfaces 231a and 232a of the first and second prepregs 231 and 232, roughness of the first and second prepregs 231 and 232 are very high.

In the fourth process 141, copper plating is performed on the surfaces 231a and 232a of the first and second prepregs 231 and 232. The fourth process 141 is performed by performing the following three steps.

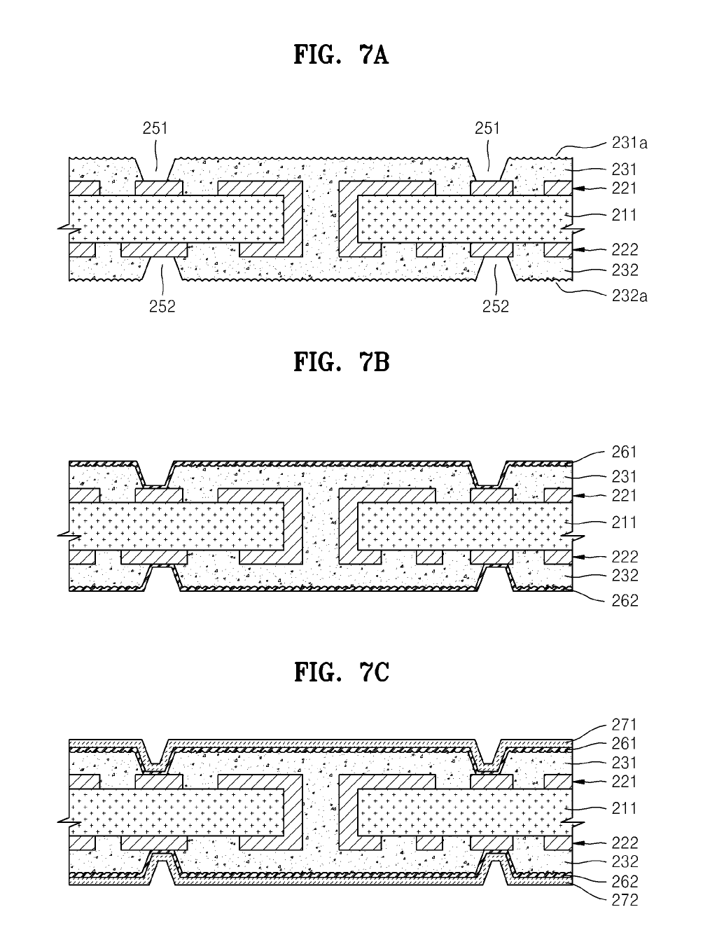

In a first step, referring to FIG. 7A, one or more craters 251 and 252 are respectively formed in the first and second prepregs 231 and 232 such that some of copper wires included in the first and second circuit patterns 221 and 222 are exposed to the outside. A mechanical method may be used in order to form the craters 251 and 252 in the first and second prepregs 231 and 232. That is, the craters 251 and 252 are formed in the first and second prepregs 231 and 232 by drilling. Some of wires constituting the first and second circuit patterns 221 and 222 are exposed to the outside through the craters 251 and 252. A chemical method may be used in order to form the craters 251 and 252. In this case, the chemical method is more complex than the mechanical method. If the craters 251 and 252 are formed by using a mechanical method, smears of the first and second prepregs 231 and 232 may be generated around the first and second prepregs 231 and 232. Therefore, after the craters 251 and 252 are formed in the first and second prepregs 231 and 232, cleaning may be further performed in order to remove the smears generated around the craters 251 and 252.

In a second step, referring to FIG. 7B, seed layers 261 and 262 composed of copper are formed by using non-electrolytic plating on the surfaces 231a and 232a of the prepregs 231 and 232 in which the craters 251 and 252 are formed. The seed layers 261 and 262 are very thin. The seed layers 261 and 262 are formed on surfaces of the craters 251 and 252 and the surfaces 231a and 232a of the prepregs 231 and 232. Since the non-electrolytic plating is used, the seed layers 261 and 262 are formed on the top and bottom surfaces of the substrate 211 by reducing and depositing metal ions in a solution without flowing external current through the substrate 211.

In a third step, referring to FIG. 7C, copper plating layers 271 and 272 are formed adjoining the seed layers 261 and 262 by using electrolytic plating. The copper plating layers 271 and 272 are generally thicker than the seed layers 261 and 262.

In the fifth process 151, third and fourth circuit patterns 281 and 282 in contact with the first and second circuit patterns 221 and 222 are formed on the first and second prepregs 231 and 232. Accordingly, the circuit board 201 according to the present embodiment is completed.

In order to form the third and fourth circuit patterns 281 and 282 on the first and second prepregs 231 and 232, a dry film resist or a photoresist may be applied to the copper plating layers 271 and 272 formed on the first and second prepregs 231 and 232, and exposure, developing, and exfoliation using a mask may be performed. The exposure, developing, and exfoliation are well known and thus a detailed explanation thereof will not be given.

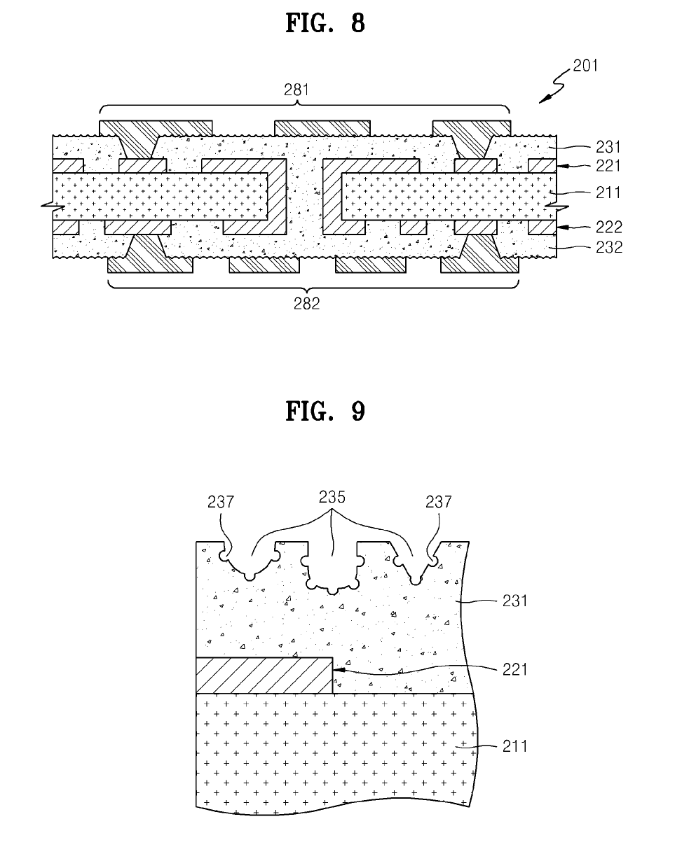

Although the first through fourth circuit patterns 221, 222, 281, and 282 are formed on both surfaces of the circuit board 201 (see FIG. 8) in FIGS. 1 through 8, one or more circuit patterns 222 and 282 may be formed on only one surface of the circuit board 201.

FIG. 9 is a cross-sectional view taken along line A-A′ of FIG. 6, for explaining a structure of the circuit board 201. Referring to FIGS. 6, 8, and 9, the circuit board 201 includes the substrate 211 and the first and second prepregs 231 and 232.

The first circuit pattern 221 is formed on the top surface of the substrate 211, and the first prepreg 231 is adhered to a top surface of the first circuit pattern 221. The plurality of first holes 235 are formed in a top surface of the first prepreg 231, and the single or plurality of auxiliary holes 237 are formed on surfaces of the plurality of first holes 235.

The second circuit pattern 222 is formed on the bottom surface of the substrate 211, and the second prepreg 232 is adhered to a bottom surface of the second circuit pattern 222. The plurality of second holes 235 are formed in a bottom surface of the second prepreg 232, and the single or plurality of auxiliary holes 237 are formed on surfaces of the plurality of second holes 235.

As such, since the plurality of holes 235 are formed on the surfaces 231 a and 232a of the first and second prepregs 231 and 232, and the auxiliary holes 237 are formed by removing the silica fillers 233 contained in the inner walls of the holes 235, surface areas of the first and second prepregs 231 and 232 are greatly increased.

Accordingly, when the copper plating layers 261, 262, 271, and 272 are formed on the surfaces 231a and 232a of the first and second prepregs 231 and 232, a peel strength between the first and second prepregs 231 and 232 and the copper plating layers 261, 262, 271, and 272 is drastically increased, thereby enabling a fine circuit pattern to be formed on the circuit board 201.

Meanwhile, referring to FIG. 8, the single or plurality of circuit patterns 281 and 282 may be further formed on the top surface of the first circuit pattern 221 and the bottom surface of the second circuit pattern 222.

According to an exemplary embodiment, since common prepregs are adhered to a top surface and a bottom surface of a substrate and a hydrofluoric acid-containing mixture is used when de-smearing is performed on the prepregs, silica fillers contained in the prepregs are removed.

Since the silica fillers contained in the prepregs are removed, surface areas of the prepregs are increased and thus a peel strength between the prepregs and copper plating layers is drastically increased when the copper plating layers are formed on the prepregs.

Since the peel strength between the prepregs and the copper plating layers is drastically increased, a fine circuit pattern may be formed on a circuit board. While exemplary embodiments have been particularly shown and described, it will be understood by one of ordinary skill in the art that various changes in form and details may be made therein without departing from the spirit and scope of the present inventive concept as defined by the following claims. The exemplary embodiments should be considered in a descriptive sense only and not for purposes of limitation.

1. A method of manufacturing a circuit board, the method comprising:
providing a substrate comprising a first circuit pattern and a first prepreg;
forming a plurality of holes on a top surface of the first prepreg;
removing silica fillers contained in inner walls of the plurality of holes; and
performing copper plating on the top surface of the first prepreg.

2. The method of claim 1, wherein the providing of the substrate comprises:
preparing the substrate where the first circuit pattern is formed on a top surface of the substrate;
sequentially disposing the first prepreg and a copper foil on the top surface of the substrate where the first circuit pattern is formed;
compressing the copper foil and the prepreg to the substrate; and
removing the copper foil.

3. The method of claim 2, wherein the copper foil is a common copper foil, and
wherein a smooth surface of the copper foil adjoins the first prepreg.

4. The method of claim 1, wherein the silica fillers are removed by using a hydrofluoric acid-containing mixture.

5. The method of claim 1, wherein the performing of the copper plating comprises:
forming one or more craters on the top surface of the first prepreg to expose copper wires included in the first circuit pattern to the outside;
forming a seed layer formed of copper by using non-electrolysis means on a top surface of the first prepreg where the one or more craters are formed; and
forming a copper plating layer on the seed layer by using electrolysis means.

6. The method of claim 1 further comprising:
providing the substrate with a second circuit pattern and a second prepreg;
forming a plurality of second holes on a bottom surface of the second prepreg;
removing silica fillers contained in inner walls of the plurality of second holes; and
performing copper plating on the bottom surface of the second prepreg.

7. The method of claim 6, wherein the second circuit pattern and the second prepreg are sequentially stacked on a top surface of the substrate.

8. The method of claim 6, wherein the first circuit pattern on the top surface of the substrate and the second circuit pattern on the bottom surface of the substrate are in contact.

9. The method of claim 6, wherein the second prepreg is a common prepreg commonly used in a multi-layer substrate.

10. The method of claim 6, wherein the first prepreg and the second prepreg are in contact.

11. The method of claim 6 further comprising forming a fourth circuit pattern on the bottom surface of the second prepreg, wherein the fourth circuit pattern is in contact with the second circuit pattern.

12. The method of claim 1, wherein the first circuit pattern and the prepreg are sequentially stacked on a top surface of the substrate.

13. The method of claim 1, wherein the first prepreg comprises an insulating material.

14. The method of claim 1, wherein the first prepreg is a common prepreg commonly used in a multi-layer substrate.

15. The method of claim 1 further comprising:
forming a third circuit pattern on the top surface of the first prepreg,
wherein the third circuit pattern is in contact with the first circuit pattern.

16. The method of claim 1, wherein the forming the plurality of holes on a top surface of the first prepreg comprises:
performing desmearing on the top surface of the first prepreg; and
performing swelling on the top surface of the first prepreg.

17. A circuit board comprising:
a substrate;
a first circuit pattern formed on a top surface of the substrate;
a prepreg adhered to the first circuit pattern;
a plurality of first holes formed in a top surface of the prepreg; and
one or more first auxiliary holes formed on surfaces of the plurality of first holes by removing silica fillers contained in inner walls of the plurality of first holes.

18. The circuit board of claim 17, further comprising:
a second circuit pattern formed on a bottom surface of the substrate;
a second prepreg adhered to a bottom surface of the second circuit pattern;
a plurality of second holes formed in a bottom surface of the second prepreg; and
one or more second auxiliary holes formed on surfaces of the plurality of second holes by removing silica fillers contained in the inner walls of the plurality of second holes.

19. The circuit board of claim 17, further comprising a third circuit pattern on the top surface of the first prepreg, wherein the third circuit pattern is in contact with the first circuit pattern

20. The circuit board of claim 18, further comprising a fourth circuit pattern on the bottom surface of the second prepreg, wherein the fourth circuit pattern is in contact with the second circuit pattern.
